(19) United States
(12) Patent Application Publication
(10) Pub. No.: US 2026/0150720 A1
(43) Pub. Date: May 28, 2026

(54) CHIP PACKAGE WITH REDISTRIBUTION CIRCUIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/365,197

(22) Filed: Oct. 22, 2025

(30) Foreign Application Priority Data
Nov. 22, 2024 (TW) 113145146

(51) Int. Cl. H01L 23/00

(52) U.S. Cl. CPC H10W 70/60; H10W 70/09

(57) ABSTRACT

A chip package with redistribution circuits is provided. The chip package includes a chip, a plurality of redistribution circuits, and a plurality of nickel immersion gold layers. The redistribution circuits are formed and horizontally extending on the surface of the chip by a redistribution layer (RDL) process. The nickel immersion gold layer is plated on a surface of the redistribution circuit by an electroless nickel immersion gold (ENIG) process. Each of the nickel immersion gold layers is formed by a nickel layer and a gold layer located over the nickel layer. Thereby problems of the chip package available now including uneven thickness of the nickel immersion gold layer caused by electroplating process and the complex manufacturing process can be solved. The design space and reliability of the chip package are effectively improved by the RDL process.

### CROSS-REFERENCE TO RELATED APPLICATIONS

This non-provisional application claims priority under 35 U.S.C. § 119(a) on Patent Application No(s). 113145146 filed in Taiwan, R.O.C. on Nov. 22, 2024, the entire contents of which are hereby incorporated by reference.

### BACKGROUND OF THE INVENTION

The present invention relates to chip package with circuits, especially to a chip package with redistribution circuits.

A chip package available now includes a chip, a plurality of redistribution circuits, and a plurality of nickel immersion gold layers. The redistribution circuits are formed on a surface of the chip by a redistribution layer (RDL) process. The respective nickel immersion gold layers of the conventional chip package are coated on surfaces of the redistribution circuits by an electroplating process so that problems including uneven thickness and relatively complex manufacturing processes are easy to occur. Moreover, the electroplating process is quite energy consuming and thus not environmentally friendly. The manufacturing is not aligning with a trend in green energy and environmental protection.

### SUMMARY OF THE INVENTION

Therefore, it is a primary object of the present invention to provide a chip package with redistribution circuits. The chip package includes a chip, a plurality of redistribution circuits, and a plurality of nickel immersion gold layers. The redistribution circuits are formed and horizontally extending on a surface of the chip by a redistribution layer (RDL) process. The nickel immersion gold layer is plated on a surface of the redistribution circuits by an electroless nickel immersion gold (ENIG) process. Each of the nickel immersion gold layers is formed by a nickel layer and a gold layer located over the nickel layer. Thereby problems of the chip package available now including uneven thickness of the nickel immersion gold layer 30 caused by the electroplating and the complex manufacturing process can be solved. The design space and reliability of the die pads in the chip package are effectively improved.

In order to achieve the above objects, a chip package with redistribution circuits according to the present invention are provided. The chip package includes a chip, a plurality of redistribution circuits, and a plurality of nickel immersion gold layers. A surface of the chip is provided with a plurality of die pads. The redistribution circuits are formed and horizontally extending on the surface of the chip by a redistribution layer (RDL) process. Each of the redistribution circuits is provided with a surface. At least one dielectric layer produced by the RDL process is disposed over the surface of the chip and a plurality of grooves is extending horizontally and arranged over the dielectric layer. Each of the grooves is for allowing the corresponding die pad of the chip to be exposed. The redistribution circuits are formed by metals in the grooves and electrically connected to the die pads. The nickel immersion gold layers are disposed on the surfaces of the redistribution circuits in the grooves. Each of the nickel immersion gold layers is formed by a nickel (Ni) layer and a gold (Au) layer located over the nickel layer. The chip is electrically connected to the outside through the die pads, the redistribution circuits, and the nickel immersion gold layers in turn. The present redistribution circuits of the chip package feature on that the nickel immersion gold layer is plated on the surface of the respective redistribution circuits in the grooves by an electroless nickel immersion gold (ENIG) process. A method of manufacturing the chip package includes the following steps. Step S1: providing a chip package. The chip package includes a chip and a plurality of redistribution circuits which are formed and horizontally extending on a surface of the chip by a redistribution layer (RDL) process and electrically connected to a plurality of die pads on the surface of the chip. The redistribution circuits are formed in the following way. At first forming a dielectric layer over the surface of the chip. Then a plurality of grooves is extending horizontally and arranged over the dielectric layer. Next the redistribution circuits are formed by metal materials in the grooves which allow the die pads to be exposed correspondingly. Thus the redistribution circuits are electrically connected to the die pads. Each of the redistribution circuits is provided with a surface. Step S2: plating a plurality of nickel immersion gold layers on the surfaces of the redistribution circuits in the grooves by an electroless nickel immersion gold (ENIG) process. Each of the nickel immersion gold layers is formed by a nickel (Ni) layer and a gold (Au) layer located over the nickel layer.

Preferably, the redistribution circuits are made of copper (Cu) or aluminum (Al).

Preferably, the chip further includes a first protective layer by which a side surface of the die pad is surrounded.

Preferably, the chip further includes a second protective layer which is arranged over the first protective layer and provided with an opening for allowing the corresponding die pad to be exposed.

A chip package with redistribution circuits according to the present invention is provided. The chip package includes a chip, a plurality of redistribution circuits, and a plurality of nickel immersion gold layers. A surface of the chip is provided with a plurality of die pads. The redistribution circuits are formed and horizontally extending on the surface of the chip by a redistribution layer (RDL) process. Each of the redistribution circuits is provided with a surface and two side surfaces. The redistribution circuits are electrically connected to the die pads. The nickel immersion gold layer is arranged at the surface and the two side surfaces of the redistribution circuit. Each of the nickel immersion gold layers is formed by a nickel (Ni) layer and a gold (Au) layer located over the nickel layer. The chip is electrically connected to the outside through the die pads, the redistribution circuits, and the nickel immersion gold layers in turn. The present redistribution circuits of the chip package feature on that the nickel immersion gold layer is plated on the surface and the two side surfaces of the redistribution circuit by an electroless nickel immersion gold (ENIG) process. A method of manufacturing the chip package includes the following steps. Step S1: providing a chip package. The chip package includes a chip and a plurality of redistribution circuits which are formed and horizontally extending on a surface of the chip by a redistribution layer (RDL) process and electrically connected to the die pads. The formation the redistribution circuits is by the following way. First forming a dielectric layer over the surface of the chip. Then a plurality of grooves is extending horizontally and arranged over the dielectric layer. Next the redistribution circuits are formed by metal materials in the grooves which allow the die pads to be exposed correspondingly. Thus the redistribution circuits are electrically connected to the die pads. Each of the redistribution circuits is provided with a surface. Step S2: removing the dielectric layer around the redistribution circuit so that the two side surfaces of the redistribution circuit are exposed. Step S3: plating a plurality of nickel immersion gold layers on the surface and the two side surfaces of each of the redistribution circuits by the ENIG process. Each of the nickel immersion gold layers is formed by a nickel (Ni) layer and a gold (Au) layer located over the nickel layer.

Preferably, in the step S2, the dielectric layer is further removed from the surface of the chip completely.

Preferably, the redistribution circuits are made of copper (Cu) or aluminum (Al).

Preferably, the chip further includes a first protective layer by which a side surface of the die pad is surrounded.

Preferably, the chip further includes a second protective layer which is arranged over the first protective layer and provided with an opening for allowing the corresponding die pad to be exposed.

### BRIEF DESCRIPTION OF THE DRAWINGS

FIG. 1 is a side sectional view of an embodiment of a chip package according to the present invention;

FIG. 2 is a side sectional view of the embodiment in FIG. 1 in one direction according to the present invention;

FIG. 3 is a side sectional view of an embodiment in which grooves are formed on a dielectric layer according to the present invention;

FIG. 4 is a side sectional view of another embodiment of a chip package according to the present invention;

FIG. 5 is a side sectional view of the embodiment in FIG. 4 in one direction according to the present invention;

FIG. 6 is a side sectional view of an embodiment in which redistribution circuits are formed in grooves on a dielectric layer according to the present invention;

FIG. 7 is a side sectional view showing complete removal of the dielectric layer of the embodiment in FIG. 6 according to the present invention;

FIG. 8 is a side sectional view of a further embodiment of a chip package according to the present invention;

FIG. 9 is a side sectional view showing removal of the dielectric layer around the redistribution circuits of the embodiment in FIG. 6 according to the present invention.

### DETAILED DESCRIPTION OF THE PREFFERED EMBODIMENT

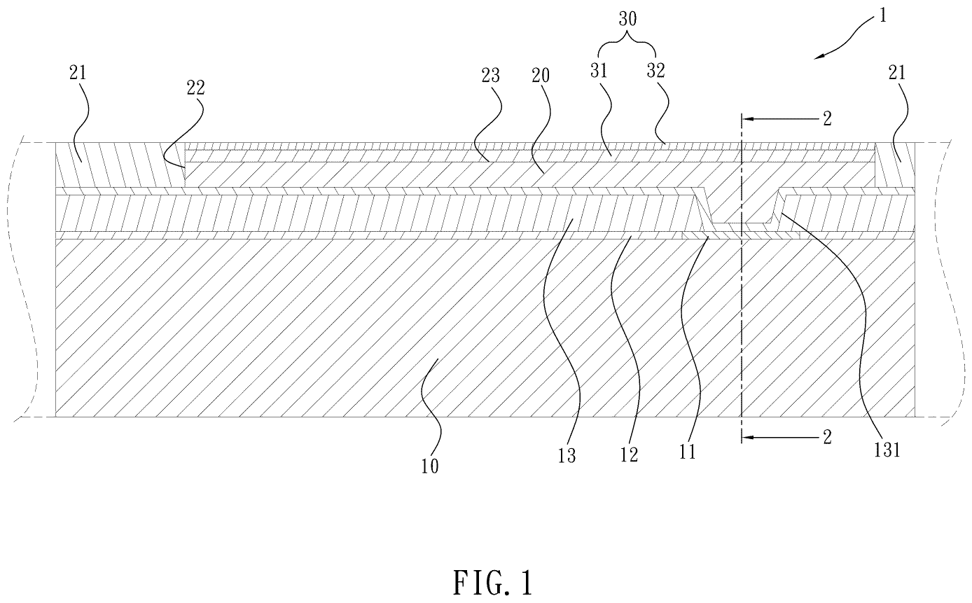

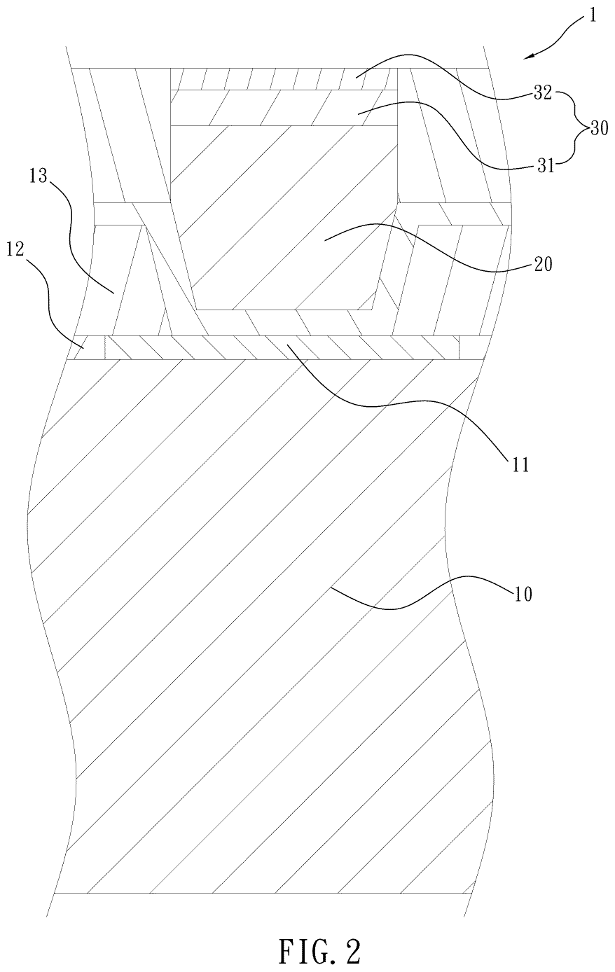

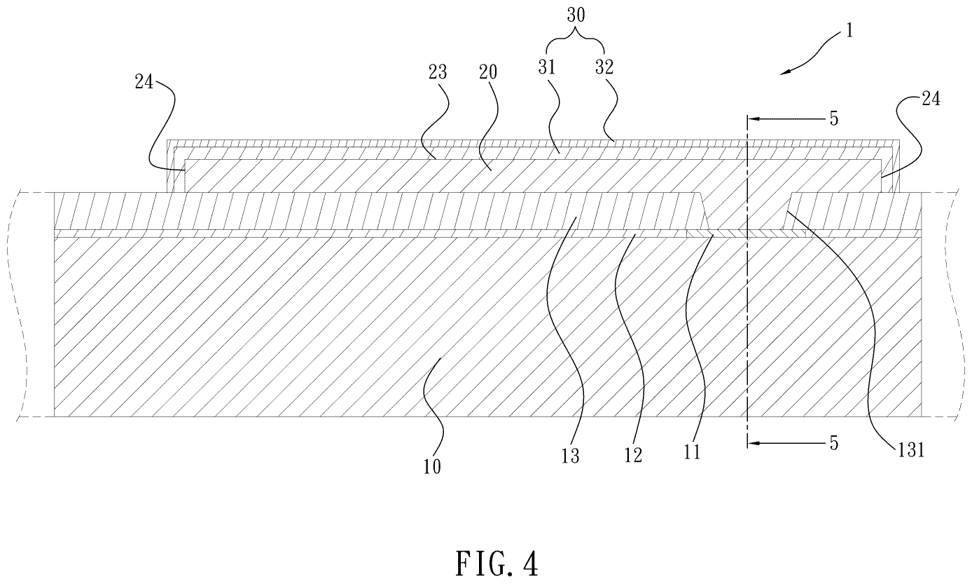

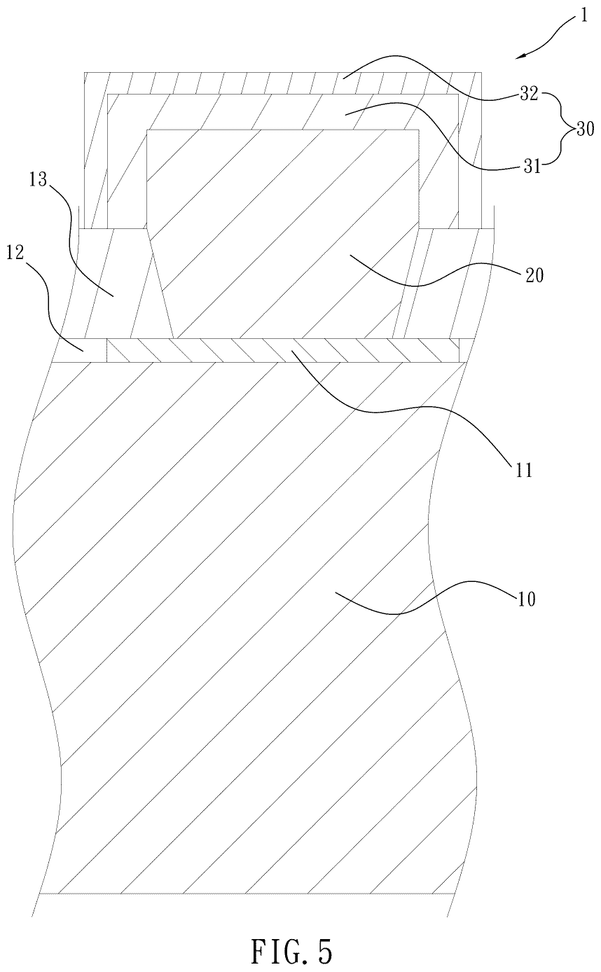

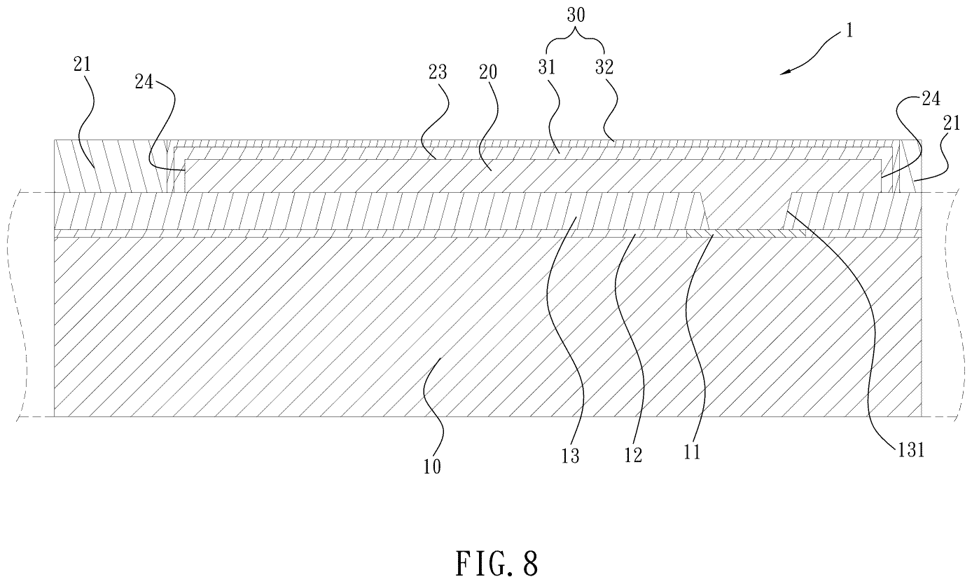

Refer to FIG. 1, FIG. 4, and FIG. 8, a chip package with redistribution circuits according to the present invention is provided. A chip package 1 of the present invention includes a chip 10, a plurality of redistribution circuits 20, and a plurality of nickel immersion gold layers 30. A surface of the chip 10 is provided with a plurality of die pads 11. The redistribution circuits 20 are formed and horizontally extending on the surface of the chip 10 by a redistribution layer (RDL) process and electrically connected to the die pads 11. The nickel immersion gold layer 30 is plated on the redistribution circuits 20 by an electroless nickel immersion gold (ENIG) process. Each of the nickel immersion gold layers 30 is formed by a nickel (Ni) layer 31 and a gold (Au) layer 32. The gold (Au) layer 32 of the nickel immersion gold layers 30 is located over the nickel layer 31, as shown in FIG. 2 and FIG. 5. The chip is electrically connected to the outside through the die pads 11, the redistribution circuits 20, and the nickel immersion gold layers 30. The nickel immersion gold layer 30 formed by the ENIG process can be more flat and even compared with a nickel immersion gold layer produced by electroplating. In the figures of the present invention, there is only one die pad 11, one redistribution circuit 20, and one nickel immersion gold layer 30 taken as an example, but not intended to limit the present invention.

Refer to FIG. 1, FIG. 4, and FIG. 8, the redistribution circuits 20 are made of copper (Cu) or aluminum (Al).

Refer to FIG. 1, FIG. 4, and FIG. 8, the chip 1 further includes a first protective layer 12 by which a side surface of the die pad 11 is surrounded.

Refer to FIG. 1, FIG. 4, and FIG. 8, the chip 1 further includes a second protective layer 13 which is arranged over the first protective layer 12 and provided with an opening 131 for allowing the corresponding die pad 11 to be exposed.

According to different types of the redistribution circuits 20, and the nickel immersion gold layers 30 formed in the chip package 1 and whether the surface of the chip 10 is provided with a dielectric layer, the chip package 1 of the present invention has three embodiments.

The chip package 1 shown in FIG. 1 is the first embodiment. Each of the redistribution circuits 20 is provided with a surface 23. At least one dielectric layer 21 produced by the RDL process is disposed over the surface of the chip 10 and a plurality of grooves 22 is extending horizontally and arranged over the dielectric layer 21. Each of the grooves 22 is for allowing the corresponding die pad 11 of the chip 10 to be exposed. The redistribution circuits 20 made of metals are formed in the grooves 22 and electrically connected to the die pads 11. The respective nickel immersion gold layers 30 are disposed on the surfaces of the respective redistribution circuits 20 in the respective grooves 22 correspondingly.

A method of manufacturing the first embodiment of the chip package 1 according to the present invention includes the following steps.

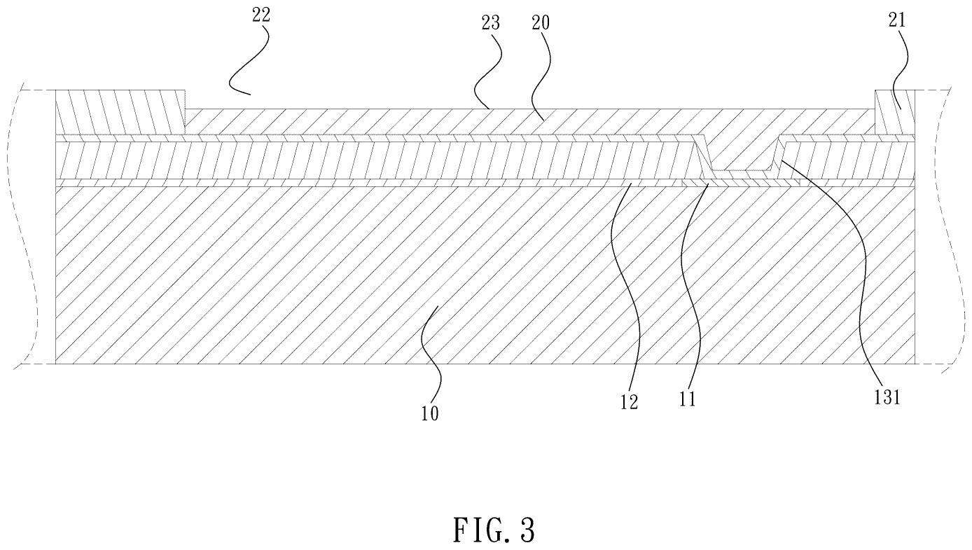

Step S1: providing a chip package 1; refer to FIG. 3, the chip package 1 includes a chip 10 and a plurality of redistribution circuits 20 which are formed and horizontally extending on a surface of the chip 10 by a redistribution layer (RDL) process and electrically connected to the die pads 11. The formation of the redistribution circuits 20 is by the following way. First forming a dielectric layer 21 over the surface of the chip 10. Then a plurality of grooves 22 is extending horizontally and arranged over the dielectric layer 21. Next the redistribution circuits 20 are formed by metal materials in the grooves 22 which allow the die pads 11 to be exposed correspondingly. Thus the redistribution circuits 20 are electrically connected to the die pads 11. Each of the redistribution circuits 20 is provided with a surface 23.

Step S2: plating a plurality of nickel immersion gold layers 30 on the surfaces 23 of the redistribution circuits 20 in the grooves 22 by an electroless nickel immersion gold (ENIG) process, as shown in FIG. 1. Each of the nickel immersion gold layers 30 is formed by a nickel (Ni) layer 31 and a gold (Au) layer 32. The gold layer 32 of the nickel immersion gold layer 30 is located over the nickel layer 31, as shown in FIG. 2.

The second embodiment is shown in FIG. 8. Each of the redistribution circuits 20 is provided with a surface 23 and two side surfaces 24. The nickel immersion gold layer 30 is arranged at the surface 23 and the two side surfaces 24 of the redistribution circuit 20.

A method of manufacturing the second embodiment of the chip package 1 according to the present invention includes the following steps.

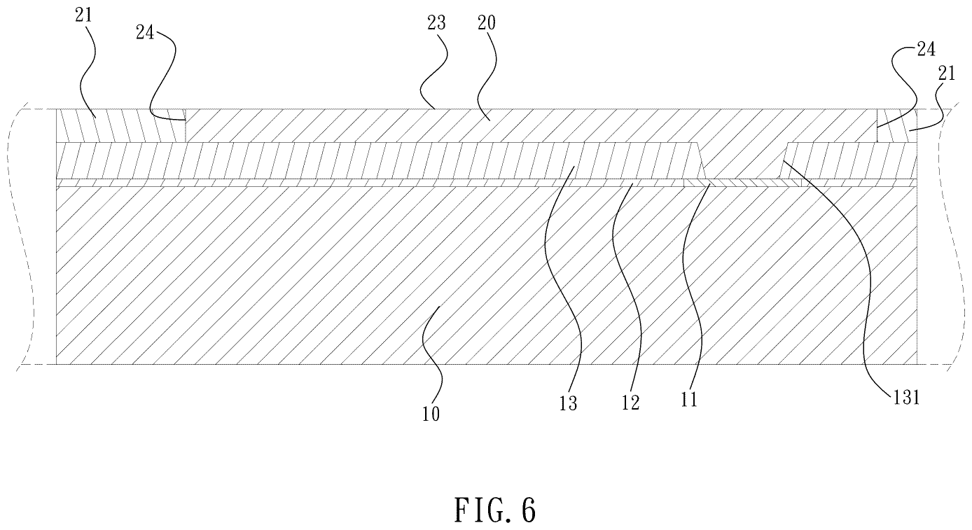

Step S1: providing a chip package 1; refer to FIG. 6, the chip package 1 includes a chip 10 and a plurality of redistribution circuits 20 which are formed and horizontally extending on a surface of the chip 10 by a redistribution layer (RDL) process and electrically connected to the die pads 11. The formation of the redistribution circuits 20 is by the following way. First forming a dielectric layer 21 over the surface of the chip 10 and then a plurality of grooves 22 is extending horizontally and arranged over the dielectric layer 21. Next the redistribution circuits 20 are formed by metal materials in the grooves 22 which allow the die pads 11 to be exposed correspondingly. Thus the redistribution circuits 20 are electrically connected to the die pads 11. Each of the redistribution circuits 20 is provided with a surface23.

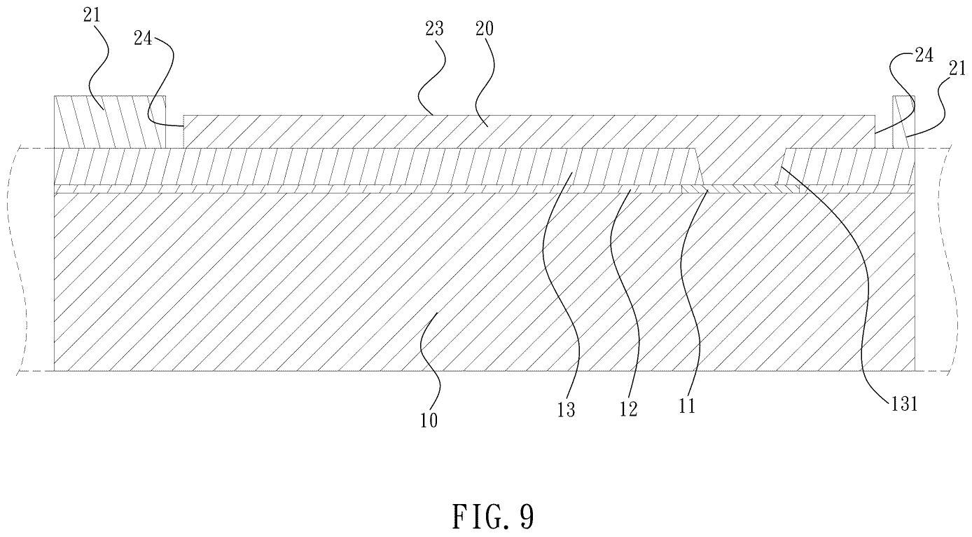

Step S2: removing the dielectric layer 21 around the redistribution circuit 20 so that the two side surfaces 24 of the redistribution circuit 20 are exposed, as shown in FIG. 9.

Step S3: plating a plurality of nickel immersion gold layers 30 on the surface 23 and the two side surfaces 24 of each of the redistribution circuits 20 by the ENIG Process, as shown in FIG. 8.

The third embodiment is shown in FIG. 4. Each of the redistribution circuits 20 is provided with a surface 23 and two side surfaces 24. The nickel immersion gold layer 30 is arranged at the surface 23 and the two side surfaces 24 of the redistribution circuit 20.

A method of manufacturing the third embodiment of the chip package 1 according to the present invention includes the following steps.

Step S1: providing a chip package 1; refer to FIG. 6, the chip package 1 includes a chip 10 and a plurality of redistribution circuits 20 which are formed and horizontally extending on a surface of the chip 10 by a redistribution layer (RDL) process and electrically connected to the die pads 11. The formation of the redistribution circuits 20 is by the following way. First forming a dielectric layer 21 over the surface of the chip 10 and then a plurality of grooves 22 is extending horizontally and arranged over the dielectric layer 21. Next the redistribution circuits 20 are formed by metal materials in the grooves 22 which allow the die pads 11 to be exposed correspondingly. Thus the redistribution circuits 20 are electrically connected to the die pads 11. Each of the redistribution circuits 20 is provided with a surface 23.

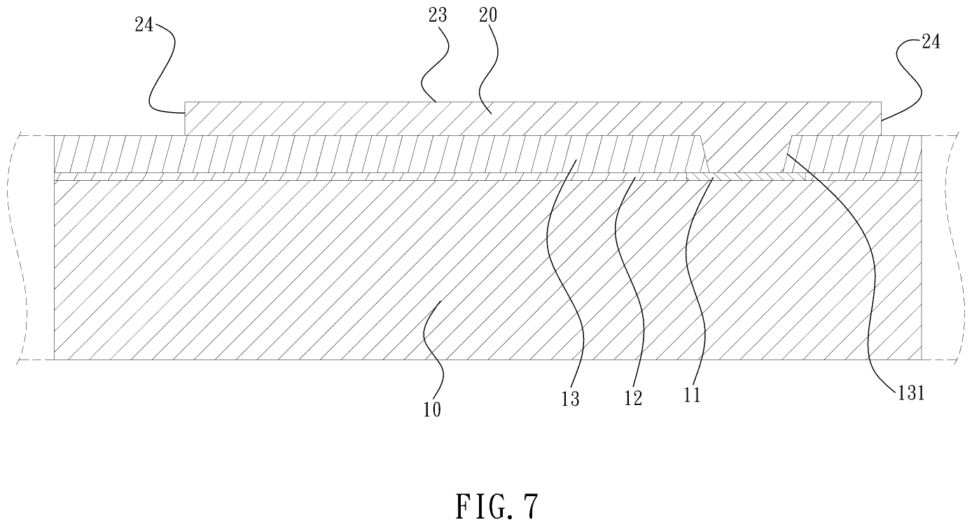

Step S2: removing the dielectric layer 21 around the redistribution circuit 20 so that the two side surfaces 24 of the redistribution circuit 20 are exposed, as shown in FIG. 7. The dielectric layer 21 is completely removed from the surface of the chip 10.

Step S3: plating a plurality of nickel immersion gold layers 30 on the surface 23 and the two side surfaces 24 of each of the redistribution circuits 20 by the ENIG process, as shown in FIG. 8.

Compared with the chip package available now, the chip package of the present invention includes the following advantages.
(1) The nickel immersion gold layers 30 are plated on the redistribution circuits 20 by the ENIG process. The problems of the chip package available now including uneven thickness of the nickel immersion gold layer 30 caused by the electroplating and the complex manufacturing process can be solved. This not only helps improvement of product reliability and reduction of manufacturing cost, energy-saving and environmental protection are also achieved.
(2) The redistribution circuits 20 are formed and horizontally extending on a surface of the chip 10 by a redistribution layer (RDL) process. The RDL process is implemented precisely and easily so that the manufacturing process is more simplified. A light weight and compact design is achieved under condition that the redistribution circuits 20 still have electrical extension in the XY plane and interconnections.
(3) The nickel immersion gold layer 30 is a metal stacked structure with a certain thickness, as shown in FIG. 2 and FIG. 5 so that the structural strength of the redistribution circuits 20 is increased. For example, when wire bonding is selected to electrically connect the chip package 1 with the outside, the nickel immersion gold layer 30 can withstand positive pressure generated during wire bonding or formation of bonding points. Thereby the redistribution circuits 20 will not be easily damaged by the positive pressure.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip package with redistribution circuits comprising: a chip, a plurality of the redistribution circuits, and a plurality of nickel immersion gold layers;
wherein a surface of the chip is provided with a plurality of die pads; wherein the redistribution circuits are formed and horizontally extending on the surface of the chip by a redistribution layer (RDL) process and each of the redistribution circuits is provided with a surface; wherein at least one dielectric layer produced by the RDL process is disposed over the surface of the chip and a plurality of grooves is extending horizontally and arranged over the dielectric layer; each of the grooves is for allowing the corresponding die pad of the chip to be exposed; wherein the redistribution circuits are formed by metals in the grooves and electrically connected to the die pads; wherein the nickel immersion gold layers are disposed on the surfaces of the redistribution circuits in the grooves; wherein each of the nickel immersion gold layers is formed by a nickel (Ni) layer and a gold (Au) layer located over the nickel layer; wherein the chip is electrically connected to the outside through the die pads, the redistribution circuits, and the nickel immersion gold layers in turn; wherein the chip package features on that the nickel immersion gold layer is plated on the surface of the respective redistribution circuits in the grooves by an electroless nickel immersion gold (ENIG) process;
wherein a method of manufacturing the chip package comprising the steps of:
Step S1: providing a chip package; the chip package having a chip and a plurality of redistribution circuits which is formed and horizontally extending on a surface of the chip by the RDL process; the redistribution circuits are electrically connected to a plurality of die pads on the surface of the chip; wherein the redistribution circuits is formed by firstly forming a dielectric layer over the surface of the chip; then a plurality of grooves is extending horizontally and arranged over the dielectric layer; and next the redistribution circuits are formed by metal materials in the grooves; wherein the grooves allow the die pads to be exposed correspondingly so that the redistribution circuits are electrically connected to the die pads; wherein each of the redistribution circuits is provided with a surface; and
Step S2: plating a plurality of nickel immersion gold layers on the surfaces of the redistribution circuits in the grooves by the ENIG process; wherein each of the nickel immersion gold layers is formed by a nickel (Ni) layer and a gold (Au) layer located over the nickel layer.

2. The chip package with redistribution circuits as claimed in claim 1, wherein the redistribution circuits are formed by copper (Cu) or aluminum (Al).

3. The chip package with redistribution circuits as claimed in claim 1, wherein the chip further includes a first protective layer by which a side surface of the die pad is surrounded.

4. The chip package with redistribution circuits as claimed in claim 3, wherein the chip further includes a second protective layer which is arranged over the first protective layer; wherein the second protective layer is provided with an opening for allowing the corresponding die pad to be exposed.

5. A chip package with redistribution circuits comprising: a chip, a plurality of the redistribution circuits, and a plurality of nickel immersion gold layers;
wherein a surface of the chip is provided with a plurality of die pads; wherein the redistribution circuits are formed and horizontally extending on the surface of the chip by a redistribution layer (RDL) process and each of the redistribution circuits is provided with a surface and two opposite side surfaces; wherein the redistribution circuits are electrically connected to the die pads; wherein the nickel immersion gold layer is arranged at the surface and the two side surfaces of the redistribution circuit correspondingly; wherein each of the nickel immersion gold layers is formed by a nickel (Ni) layer and a gold (Au) layer located over the nickel layer; wherein the chip is electrically connected to the outside through the die pads, the redistribution circuits, and the nickel immersion gold layers in turn; wherein the chip package with the redistribution circuits features on that the nickel immersion gold layer is plated on the surface and the two side surfaces of the redistribution circuit by an electroless nickel immersion gold (ENIG) process; wherein a method of manufacturing the chip package comprising the steps of:
Step S1: providing a chip package; wherein the chip package includes a chip and a plurality of redistribution circuits which are formed and horizontally extending on a surface of the chip by the redistribution layer process (RDL) process and electrically connected to a plurality of die pads on the surface of the chip; wherein the redistribution circuits is formed by firstly forming a dielectric layer over the surface of the chip; then a plurality of grooves is extending horizontally and arranged over the dielectric layer; and next the redistribution circuits are formed by metal materials in the grooves; wherein the grooves allow the die pads to be exposed correspondingly so that the redistribution circuits are electrically connected to the die pads; wherein each of the redistribution circuits is provided with a surface;
Step S2: removing the dielectric layer around the redistribution circuit so that the two side surfaces of the redistribution circuit are exposed; and
Step S3: plating a plurality of nickel immersion gold layers on the surface and the two side surfaces of each of the redistribution circuits by the ENIG process; wherein each of the nickel immersion gold layers is formed by a nickel (Ni) layer and a gold (Au) layer located over the nickel layer.

6. The chip package with redistribution circuits as claimed in claim 5, wherein in the step S2, the dielectric layer is further removed from the surface of the chip completely.

7. The chip package with redistribution circuits as claimed in claim 5, wherein the redistribution circuits are formed by copper (Cu) or aluminum (Al).

8. The chip package with redistribution circuits as claimed in claim 5, wherein the chip further includes a first protective layer by which a side surface of the die pad is surrounded.

9. The chip package with redistribution circuits as claimed in claim 8, wherein the chip further includes a second protective layer which is arranged over the first protective layer; wherein the second protective layer is provided with an opening for allowing the corresponding die pad to be exposed.
